(19) United States
(12) Patent Application Publication
(10) Pub. No.: US 2010/0048119 A1
(43) Pub. Date: Feb. 25, 2010

(54) Data center

(75) Inventor: Kanji Tashiro, Hitachinaka (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: HITACHI CABLE, LTD., Tokyo (JP)

(21) Appl. No.: 12/457,843

(22) Filed: Jun. 23, 2009

(30) Foreign Application Priority Data
Aug. 19, 2008 (JP) 2008-210727

(51) Int. Cl. H05K 5/00

(52) U.S. Cl. 454/184

(57) ABSTRACT

A data center includes an air-conditioned room, two rack rows formed on a floor surface of the air-conditioned room and each composed of a plurality of racks arranged in a horizontal direction, each of the plurality of racks housing electronic devices in multistage configuration, an air conditioner for conditioning air in the air-conditioned room to eliminate heat generated from the electronic devices housed in the plurality of racks, and a hot zone in the air-conditioned room. The hot zone is defined by the two rack rows arranged on the floor surface of the air-conditioned room such that rear sides thereof are opposite each other at a distance, a ceiling disposed above the two rack rows, two panels disposed at both ends of the two rack rows in the horizontal direction and extending from a lower end of the two rack rows to the ceiling, and two partitions disposed at an upper front top end of the two rack rows and extending to the ceiling. The ceiling includes an exhaust port for discharging heat in the hot zone, and the air conditioner is operable to introduce air-conditioned air from the air-conditioned room through front sides and then the rear sides of the two rack rows into the hot zone.

The present application is based on Japanese Patent Application No. 2008-210727 filed on Aug. 19, 2008, the entire contents of which are incorporated herein by reference.

### BACKGROUND OF THE INVENTION

1. Field of the Invention

The invention relates to a data center that heat generated from an electronic device such as a server housed in a rack can be efficiently eliminated.

2. Related Art

In general, electronic devices such as a server, etc., are housed in racks with high density in multi-tiers, and are arranged in an air-conditioned room. Since heat is generated in the electronic device in accordance with power consumption, air-conditioned air (cool air) is generally supplied to the electronic device housed in the rack by a cooling system such as an air conditioner for removing the heat generated in the electronic device in order to eliminate an adverse effect due to the heat.

As shown in FIG. 7, a conventional data center is entirely configured by providing one or plural so-called modular data centers 70 in an air-conditioned room, the modular data center 70 in which rack rows 72 are formed in an air-conditioned room by horizontally aligning plural racks 71 housing electronic devices such as a server, etc., the rack rows 72 are arranged on a floor surface so that rear sides thereof face each other at a distance, the air-conditioned room is divided by providing a door 75 and a roof panel 74 in a horizontal direction of the face-to-face rack rows 72, i.e., on edge sides in a longitudinal direction so as to block a gap between the rack rows 72 for defining a hot zone between the back-to-back rack rows 72 on the rear sides thereof (for example, see JP-A 2006-526205). The door 75 is for entering inside the hot zone.

In addition, in a data center of JP-A 2006-526205 in which the modular data centers 70 is provided in the air-conditioned room, one of the racks 71 incorporates a cooling device (an air conditioner), and the air in the hot zone is cooled down and exhausted to the front side of the rack 71. In other words, in the modular data centers 70, air-conditioned air (cool air) is introduced from the front side of the rack 71 for removing the heat generated in the electronic device in the rack 71, the heat-absorbed air is exhausted to the hot zone from the rear side of the rack 71, and the air in the hot zone is cooled down by the cooling device and is exhausted to the front side of the rack 71.

A coolant supply and return pipe 76 for supplying a coolant such as water or chlorofluorocarbon, etc., is connected to the cooling device which is housed in the rack 71. Electric power is supplied to each electronic device in the rack 71 via a power supply line 77.

Thus, it is possible to effectively operate the cooling device by concentrating heat generated in the electronic device in a specific space (a hot zone). In other words, since it is not necessary to supply a low-temperature coolant equivalent to that for general air-conditioning facilities to the cooling device, it is possible to efficiently produce air-conditioned air (cool air) at a low cost without dehumidification.

However, in the above-mentioned data center, the heat generated in the electronic device is discharged into the air-conditioned room from an upper surface of the rack 71 (the rack row 72) and an upper surface of the roof panel 74 which may cause mixture of the heat with air-conditioned air (cool air) produced by the cooling device which is blown from the front side of the rack 71, and a result of the mixture, when it is not possible to sufficiently cool down the temperature of the air-conditioned air (cool air) introduced from the front side of the rack 71, it is necessary to further cool down the air-conditioned air beforehand by an air conditioner (an indoor air conditioner) other than the cooling device which is incorporated in the modular data center 70. Under such circumstances, energy consumed in the air conditioner (the indoor air conditioner) is wasted, thus, there is a problem from the viewpoint of energy saving.

Since there is a type of server which exhausts the air upwards, when such a server is housed in the rack 71, a large amount of heat is discharged from the upper surface of the rack 71 into the air-conditioned room, thus, the above-mentioned problem remarkably occurs.

The data center of FIG. 7 has a further problem from the viewpoint of earthquake proof.

In earthquake-prone areas, it is essential to apply a seismic isolation structure to the rack 71 for managing important data. Since the seismic isolation structure is based on the premise that the rack 71 itself does not shake even when a building shakes due to an earthquake, displacement is generated between the building and the rack 71. It is said that an amount of horizontal displacement (displacement between the building and the rack 71) may exceed 1 m depending on a magnitude of an earthquake.

However, in the data center of FIG. 7, since a main coolant pipe is provided from an outdoor equipment along the building for supplying a coolant to the cooling device in the rack 71 from the outdoor equipment installed on the building and the main coolant pipe is connected to the cooling device in the rack 71 by a slightly thinner coolant supply and return pipe 76, when the seismic isolation structure is applied to the rack 71 (the rack row 72), there is a problem that displacement difference is generated between the main coolant pipe and the cooling device in the rack 71 in the event of an earthquake and the coolant supply and return pipe 76 is damaged. Therefore, even if the cooling device is redundantly configured in the modular data center 70 of the data center, there is a possibility that all equipments are damaged.

Furthermore, when the coolant is water, water leaking from the damaged portion of the coolant supply and return pipe 76 may fall on the electronic device such as a server and may cause severe damage thereto, and when the coolant is chlorofluorocarbon, the chlorofluorocarbon may be released into the air-conditioned room and may cause an accident resulting in injury or death.

### THE SUMMARY OF THE INVENTION

Therefore, it is an object of the invention to provide a data center which reduces energy consumption in an air-conditioned room by efficiently eliminating heat generated from the electronic devices in the rack.

In addition, it is another object of the invention to provide a data center having a seismic isolation structure so as not to cause damage to the electronic device such as a server housed in the rack even when a strong earthquake happens.

(1) According to one embodiment of the invention, a data center comprises:

an air-conditioned room;

two rack rows formed on a floor surface of the air-conditioned room and each composed of a plurality of racks arranged in a horizontal direction, each of the plurality of racks housing electronic devices in multistage configuration;

an air conditioner for conditioning air in the air-conditioned room to eliminate heat generated from the electronic devices housed in the plurality of racks; and

a hot zone in the air-conditioned room, the hot zone being defined by the floor surface, the two rack rows arranged on the floor surface of the air-conditioned room such that rear sides thereof are opposite each other at a distance, a ceiling disposed above the two rack rows, two panels disposed at both ends of the two rack rows in the horizontal direction and extending from a lower end of the two rack rows to the ceiling, and two partitions disposed at a front top end of the two rack rows and extending to the ceiling,

wherein the ceiling comprises an exhaust port for discharging heat in the hot zone, and

the air conditioner is operable to introduce air-conditioned air from the air-conditioned room through front sides and then the rear sides of the two rack rows into the hot zone.

In the above embodiment (1), the following modifications and changes can be made.

(i) The two rack rows are disposed on a seismic isolator mounted on the floor surface.

(ii) The panels and the partitions are disposed such that top ends thereof are movable with respect to the ceiling, and comprise a ceiling sealing member at the top ends for sealing the hot zone and the air-conditioned room.

(iii) The two rack rows are arranged at the distance to form a work passage, and the panels comprise a door for entering the work passage.

(iv) The partitions and/or panels comprise a connecting duct for wiring a cable connected to the electronic devices in the plurality of racks.

(v) The air conditioner is separated from the hot zone.

### Points of the Invention

According to one embodiment of the invention, a data center is constructed such that a hot zone is defined by a floor surface, two rack rows arranged on the floor surface of the air-conditioned room such that rear sides thereof are opposite each other at a distance, a ceiling disposed above the two rack rows, two panels disposed at both ends of the two rack rows in the horizontal direction and extending from a lower end of the two rack rows to the ceiling, and two partitions disposed at a front top end of the two rack rows and extending to the ceiling. Thus, heat discharged from the top of the rack can be discharged not into the air-conditioned room but into the hot zone so that all of heat generated from the electronic device can be concentrated in the hot zone and the air conditioner can be efficiently operated. In addition, unlike the conventional data center, the rack rows are completely separated from the air conditioner (i.e., not connected thereto by pipes etc.) or the hot zone and the rack rows are mounted on a seismic isolator, so that, even when a strong earthquake breaks out, there will be no risk that coolant, chlorofluorocarbon etc. leaks out due to breakage of the pipes for coolant, etc., or that the electronic device is damaged due to water falling on the rack row.

### BRIEF DESCRIPTION OF THE DRAWINGS

Next, the present invention will be explained in more detail in conjunction with appended drawings, wherein:

FIG. 1 is a schematic cross sectional view showing a data center of the invention;

FIG. 2 is a plan view showing the data center of the invention;

FIG. 3 is a side view showing the data center of the invention;

FIG. 4 is a front view showing the data center of the invention;

FIG. 5 is a schematic cross sectional view showing the data center of the invention when a connecting duct is provided;

FIG. 6 is an explanatory view showing air flow in the data center of the invention; and

FIG. 7 is a perspective view showing a conventional data center.

### DESCRIPTION OF THE PREFERRED EMBODIMENTS

### Embodiments

Preferred embodiments according to the invention will be explained as below in conjunction with appended drawings.

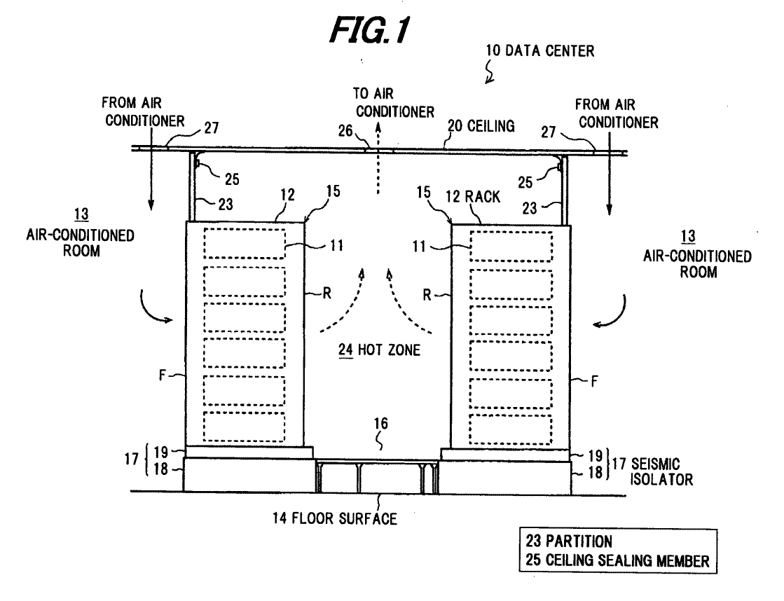

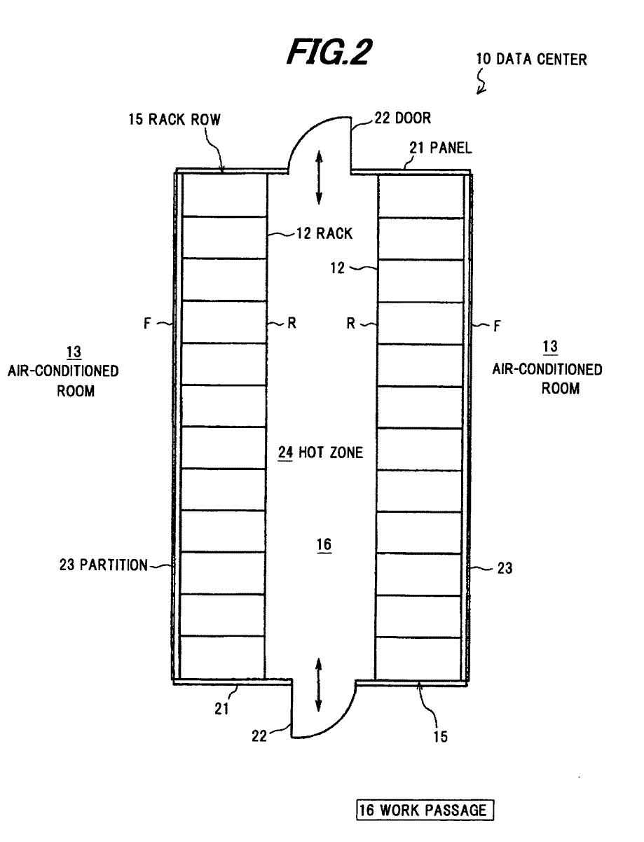

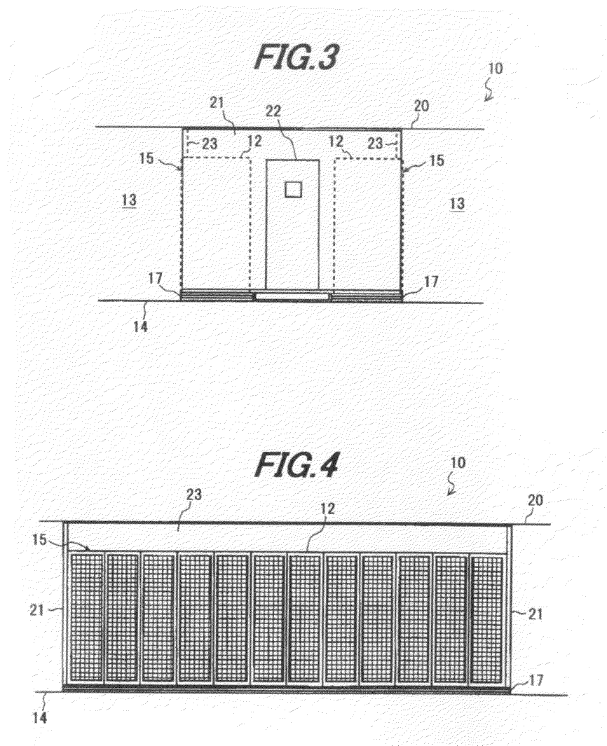

FIG. 1 is a schematic cross sectional view showing a data center in the preferred embodiment, FIG. 2 is a plan view thereof, FIG. 3 is a side view thereof, and FIG. 4 is a front view thereof.

As shown in FIGS. 1 to 4, a data center 10 includes at least a box-shaped air-conditioned room 13 composed of a ceiling, a floor surface and four side walls, a rack row 15 formed by horizontally aligning plural racks 12 housing electronic devices 11 such as a sever, etc., in multi-tiers, and an air conditioner (not shown) for conditioning air inside the air-conditioned room 13 in order to eliminate heat generated from the electronic device 11 which is housed in the rack 12.

The electronic devices 11, which are equipments for information and communication technology such as a server, a CPU, a network equipment or a storage device, are housed in the racks 12 in multi-tiers.

In the data center 10, the rack row 15 is formed by horizontally aligning the plural racks 12 (twelve racks in the embodiment) on a floor surface 14 of the air-conditioned room 13, and the rack rows 15 are arranged so that rear sides R thereof face each other at a distance. A work passage 16 is formed between the rack rows 15 by arranging the rack rows 15 at a distance.

The rack rows 15 are arranged on the floor surface 14 via a seismic isolator 17. As the seismic isolator 17, a seismic isolation platform 19 is provided on a base 18 via a bearing in the embodiment, however, it is not limited thereto.

Panels 21 extending from a lower edge of the rack row 15 to a ceiling 20 are provided on right and left sides of the rack row 15. A door 22 for entering and leaving the work passage 16 is provided on the panel 21. The panel 21 is provided on the seismic isolator 17.

A partition 23 extending to the ceiling 20 is provided at an upper front edge of each rack row 15. The partition 23 and the panel 21 are provided so that upper edges thereof are movable with respect to the ceiling 20.

A ceiling sealing members 25 for sealing a hot zone 24 and the air-conditioned room 13 is provided at the upper edges of the panel 21 and the partition 23. In the embodiment, a rubber sheet is used as the ceiling sealing member 25, and the rubber sheet is fixed at the upper edge of the partition 23 on the hot zone 24 side by a bolt, etc., so that a top end portion thereof carves toward the hot zone 24 side.

As a result, the hot zone 24, which is divided from the air-conditioned room 13 by the both rack rows 15, the partition 23 and the panel 21, is defined and formed.

An exhaust port 26 for exhausting heat in the hot zone 24 is formed on the ceiling 20 in the hot zone 24, and the exhaust port 26 is connected to an inlet port of the air conditioner via a non-illustrated exhaust air duct.

An outlet port 27 for blowing out air-conditioned air (cool air) from the air conditioner is formed on the ceiling 20 outside of the hot zone 24 (the ceiling 20 on a front side of the rack rows 15 in FIG. 1). The outlet port 27 is connected to an air-conditioned air outlet port of the air conditioner via a non-illustrated outlet duct.

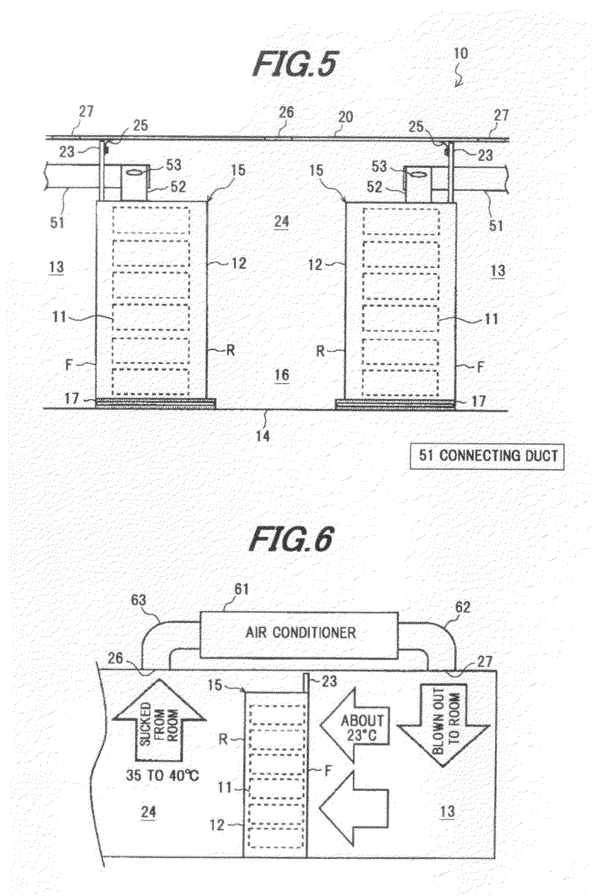

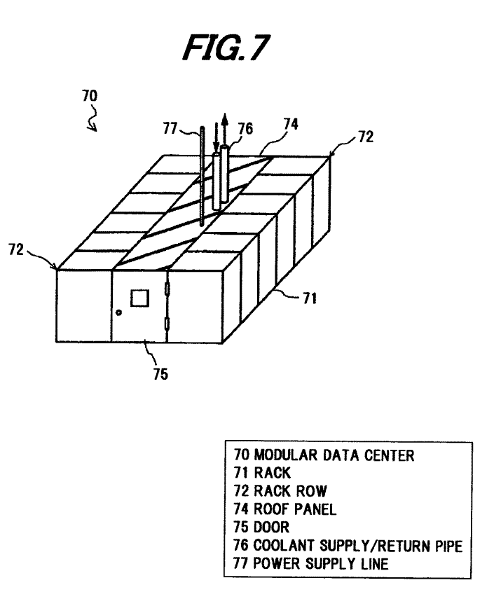

The air conditioner is provided in a space other than the air-conditioned room 13 having the racks 12 arranged therein, e.g., in another room of the building where the data center 10 is established, or outside of the building. As a result, unlike the JP-A 2006-526205, pipes for coolant, etc., are not connected to the rack 12 (the rack row 15) and the air conditioner is completely separated from the rack 12 (the rack row 15). In FIG. 6, although the air conditioner is shown as a numeral 61 and is illustrated as if being provided above the ceiling, it is just for convenience.

In addition, for example, when the air conditioner is installed in another space adjacent to the air-conditioned room 13, a floor surface level of the other space is desirably lower than that of the air-conditioned room 13. This is a device for making the coolant less likely to enter the inside of the air-conditioned room even if a coolant supply and return pipe related to the air conditioner is damaged and the coolant flows out.

As shown in FIG. 5, a connecting duct 51 for wiring a cable such as a LAN cable connected to the electronic device 11 in the rack 12 is provided in the partition 23 (or the panel 21) so as to penetrate through the partition 23 (or the panel 21). Thus, all wirings such as cables, etc., are provided on the seismic isolator 17.

The connecting duct 51 is provided above the upper surface of the rack 12 via a connecting duct pedestal 52. A long hole 53 is formed on a side surface of the connecting duct pedestal 52, and the connecting duct 51 is provided movable in a longitudinal direction thereof (a horizontal direction in the figure) by fitting a rib (not shown) formed on a side surface of the end portion of the connecting duct 51 into the long hole 53. As a result, even though an amount of displacement of the rack rows 15 on both edges of the connecting duct 51 is different in the event of an earthquake, it is possible to compensate the amount of displacement by the movement of the connecting duct 51.

Wirings (high-capacity optical fiber cables or power supply cables which are connected to exterior), essential between the building where the data center 10 is established and the rack rows 15, are gathered in one place (or several places), and are wired to the rack rows 15 in the air-conditioned room 13 through a hole formed on the ceiling 20. Each cable has a sufficient length and the hole formed on the ceiling 20 is formed in a size sufficiently large for allowing each cable to freely move corresponding to a displacement difference in the event of an earthquake.

### Functions and Effects of the Embodiment

Functions and effects of the above embodiments will be explained below.

As shown in FIG. 6, the air-conditioned air (cool air) blown out from the air-conditioned air outlet port of the air conditioner 61 is blown out from the outlet port 27 via an outlet duct 62, and is introduced into the air-conditioned room 13. The temperature of the air-conditioned air in the air-conditioned room 13 is, e.g., about 23° C.

The air-conditioned air in the air-conditioned room 13 is introduced from the front side F of the rack row 15, and is introduced into the hot zone 24 from a rear side R of the rack row 15 after removing (absorbing) the heat generated in the electronic device 11 in the rack 12. The temperature in the hot zone 24 is, e.g., about 35-45° C.

The air in the hot zone 24 is exhausted from the exhaust port 26 provided on the ceiling 20 in the hot zone 24, and is introduced into an inlet port of the air conditioner 61 via an exhaust air duct 63.

In the data center 10 of the embodiment, since the rack rows 15 are arranged so that the rear sides R thereof face each other and the partition 23 is provided at an upper front edge of each rack row 15, the heat discharged from the upper surface of the rack 12 is also introduced into the hot zone 24. Thus, the heat discharged from the upper surface of the rack 12 is not discharged into the air-conditioned room 13.

Therefore, all heat generated in the electronic device 11 can be concentrated in the hot zone 24, and it is possible to efficiently operate the air conditioner 61. In addition, since the temperature in the hot zone 24 is high, it is not necessary to supply a low-temperature coolant (e.g., 6-13° C.), which is standard in the prior art, to the air conditioner 61, and it is possible to efficiently produce air-conditioned air (cool air) at a low cost without unnecessary dehumidification or humidification. Thus, a large amount of energy is not consumed in the air conditioner 61, thereby realizing energy saving.

In addition, unlike a conventional data center of JP-A 2006-526205, since it is not necessary to arrange the cooling device in the rack rows and it is possible to cool down the air in the hot zone 24 only by the air conditioner 61 which conditions the air in the air-conditioned room 13, it is possible to further reduce the energy consumed in the air conditioner 61.

Furthermore, in the embodiment, since the rack row 15 is provided on the seismic isolator 17 and the rack row 15 is completely separated from the air conditioner 61 (not connected by pipes, etc.), there is no possibility that chlorofluorocarbon is leaked due to damage of the pipes for coolant, etc., or that the electronic device 11 is damaged due to the water falling on the rack row 15 even in the event of an earthquake.

In the embodiment, since the panel 21 and the partition 23 are movable with respect to the ceiling 20, even when the displacement difference is generated between the rack 12 (the rack row 15) and the building in the event of an earthquake, the panel 21 and the partition 23 move with the rack 12 (the rack row 15), hence, there is no possibility that the rack 12 falls over.

In the embodiment, since the connecting duct 51 for wiring the cables such as LAN cables connected to the electronic devices 11 in the racks 12 is provided on the seismic isolator 17, there is no possibility that the cables are disconnected due to the displacement difference in the event of an earthquake.

In addition, by providing the ceiling sealing member 25 at the upper edges of the panel 21 and the partition 23, it is possible to seal the hot zone 24 and the air-conditioned room 13, and the panel 21 and the partition 23 can be movable with respect to the ceiling 20.

Modifications

In the above embodiment, the rack rows 15 arranged in two rows has been explained, but it is not limited thereto. It may be other geometric rows. Alternatively, the partition 23 may be provided at the upper front edge of plural racks 12 arranged instead of the panel 21.

In the above embodiment, the panels 21 extending from a lower edge of the rack row 15 to a ceiling of the air-conditioned room 13 are each provided on both edge sides of the rack row 15 in a horizontal direction so as to block a gap between the rack rows 15. However, while using one of them on one side as a panel 21 in the same manner as the embodiment, the side walls of the air-conditioned room 13 may be used for another edge side instead of the panel 21, and in this case, the side walls of the air-conditioned room 13 are assumed to be a panel 21.

The present invention is not limited to the above-mentioned embodiment, and it should be construed as embodying all modifications and alternative constructions that may occur to one skilled in the art which fairly fall within the basic teaching herein set forth.

Although the “panel” is distinguished from the “partition” in the invention, it does not mean that constituent materials are different, such that, e.g., material quality is different. A “partition” is a partition member on the rack for dividing the air-conditioned room, and a “panel” is a coupling member on an edge side of the rack row in a horizontal direction for connecting so as to block a gap between the rack rows (including the partition). The “panel” and the “partition” may have either one plate structure or a divided structure.

In conclusion, the data center described in JP-A 2006-526205 is a type in which the modular data center 70 is provided in the air-conditioned room, i.e., a completely modularized type. On the other hand, the invention is distinguished from the completely modularized type, and as described above, it is a partially modularized type which is earthquake-proof and is partially merged with the energy-saving air-conditioned room.

What is claimed is:

1. A data center, comprising:
an air-conditioned room;
two rack rows formed on a floor surface of the air-conditioned room and each composed of a plurality of racks arranged in a horizontal direction, each of the plurality of racks housing electronic devices in multistage configuration;
an air conditioner for conditioning air in the air-conditioned room to eliminate heat generated from the electronic devices housed in the plurality of racks; and
a hot zone in the air-conditioned room, the hot zone being defined by the floor surface, the two rack rows arranged on the floor surface of the air-conditioned room such that rear sides thereof are opposite each other at a distance, a ceiling disposed above the two rack rows, two panels disposed at both ends of the two rack rows in the horizontal direction and extending from a lower end of the two rack rows to the ceiling, and two partitions disposed at a front top end of the two rack rows and extending to the ceiling,
wherein the ceiling comprises an exhaust port for discharging heat in the hot zone, and
the air conditioner is operable to introduce air-conditioned air from the air-conditioned room through front sides and then the rear sides of the two rack rows into the hot zone.

2. The data center according to claim 1, wherein
the two rack rows are disposed on a seismic isolator mounted on the floor surface.

3. The data center according to claim 1, wherein
the panels and the partitions are disposed such that top ends thereof are movable with respect to the ceiling, and comprise a ceiling sealing member at the top ends for isolating the hot zone from the air-conditioned room.

4. The data center according to claim 1, wherein
the two rack rows are arranged at the distance to form a work passage, and
the panels comprise a door for entering the work passage.

5. The data center according to claim 1, wherein
the partitions and/or panels comprise a connecting duct for wiring a cable connected to the electronic devices in the plurality of racks.

6. The data center according to claim 1, wherein
the air conditioner is separated from the hot zone.
